(19) United States
(12) Patent Application Publication
(10) Pub. No.: US 2025/0171658 A1
(43) Pub. Date: May 29, 2025

(54) Stable Chemical Mechanical Planarization Polishing Compositions And Methods For High Rate Silicon Oxide Removal

(71) Applicant: Versum Materials US, LLC, Tempe, AZ (US)

(72) Inventors: Maitland Graham, Chandler, AZ (US); Lu Gan, Chandler, AZ (US); Ramon Bernasconi, Tempe, AZ (US); Maxwell Warneke, Chandler, AZ (US)

(21) Appl. No.: 18/842,609

(22) PCT Filed: Mar. 8, 2023
(86) PCT No.: PCT/US23/63947

§ 371 Date: Aug. 29, 2024

Related U.S. Application Data
(60) Provisional application No. 63/269,317, filed on Mar. 14, 2022.

(51) Int. Cl. C09G 1/02; H01L 21/3105; H01L 21/321

(52) U.S. Cl. CPC C09G 1/02; H01L 21/31053; H01L 21/3212

(57) ABSTRACT

The present Chemical Mechanical Planarization (CMP) polishing compositions, methods, and systems have low conductivity, high stability, and offer high removal rates of silicon dioxide for achieving a topographically corrected wafer surface with low defects. The CMP polishing compositions use a unique combination of silica particles, and an amino acid having at least one carboxyl group, preferably at least one amino group —NH₂, and preferably at least one imidazole group, and a silicate.

### RELATED APPLICATIONS

This application claims priority to U.S. Provisional Patent application No. 63/269,317 filed on Mar. 14, 2022, which is hereby incorporated by reference.

### BACKGROUND

The present disclosure relates to chemical mechanical planarization or polishing slurries (or compositions, or formulations), polishing methods and polishing systems for carrying out chemical mechanical planarization in the production of a semiconductor device.

Chemical Mechanical Planarization (“CMP”) polishing is a key process step in the fabrication of integrated circuits, especially polishing surfaces for the purpose of recovering a selected material and planarizing the structure. As the technology for integrated circuit devices advances, CMP polishing is used in new and different ways to meet the new performance needed for advanced integrated circuits.

The present disclosure relates to barrier chemical mechanical planarization polishing composition (or slurry) used in the production of a semiconductor device, and polishing methods for carrying out chemical mechanical planarization. In particular, it relates to barrier polishing compositions that are suitably used for polishing patterned semiconductor wafers that are composed of multi-type films, for instance, a metal layer, a barrier film, and an underlying interlayer dielectric (ILD) structure or patterned dielectric layer.

For example, in a typical barrier process, CMP polishing compositions have been developed to target tunable metal layer removal rate with high barrier film and dielectric film removal rates.

In a typical barrier process, the barrier material of a patterned wafer is removed to expose the underlying dielectric. The exposed dielectric is then polished to a specified thickness. For a manufacturing setting, a barrier CMP polishing composition that quickly removes the exposed dielectric to the target thickness can improve throughput of pattern wafers. This throughput efficiency can translate to cost savings for the semiconductor fab.

Prior works to provide the composition for metal or barrier CMP include, for example, US2005090104; US2010255681; US2011053462; US20210253904; and US2011081780.

Conventional barrier CMP slurries are typically engineered to have an alkaline pH where colloidal stability is good. Another feature of such conventionally engineered slurries is to have a high point-of-use (POU) conductivity. This feature often allows for higher material removal rates than what would be observed for the same slurry at the same alkaline pH slurry but with a lower POU conductivity.

In the specific area of barrier CMP, such a CMP composition is engineered to remove silicon dioxide at a high removal rate with similarly high or lower tantalum or tantalum nitride rate and a Cu removal rate that is targeted to be lower than the silicon dioxide rate and to achieve a topographically corrected wafer surface with low defects to prepare the wafer ready for the next downstream process step of microchip fabrication.

It should be readily apparent from the foregoing that there remains a need within the art for compositions, methods, and systems of CMP polishing that that allow for the removal rates of various layers, specifically, silicon oxide to be adjusted or tuned during CMP process to meet the polishing requirements for particular devices.

### BRIEF SUMMARY

The subject matter of the present application satisfies the need by providing Chemical mechanical Planarization (CMP) polishing compositions, methods, and systems for barrier CMP applications.

The disclosed CMP polishing composition has a low POU conductivity and unique combination of using fumed silica particles, and suitable chemical additives such as a soluble silicate, a surfactant, a base, and an amino acid having at least one carboxyl group and at least one amino group —NH₂ and an imidazole ring for example, L-histidine to provide high removal rates of silicon dioxide (such as TEOS) for achieving a topographically corrected wafer surface with low defects.

The disclosed CMP polishing compositions use a unique combination of non-spherical, non-surface modified fumed silica particles.

In a first main aspect, a CMP composition comprises: water; an oxidizing agent; an abrasive comprising silica particles; a first chemical additive comprising one or more amino acids having at least one carboxyl group and preferably at least one amino group —NH₂ and preferably at least one imidazole group and mixtures thereof; and a second chemical additive comprising a silicate; and, optionally, a corrosion inhibitor; a surfactant; a pH adjusting agent; a biocide; wherein the polishing composition has a pH of 7 to 12, 8 to 11.5, or 10 to 11; and wherein the polishing composition has a POU conductivity of 1 mS/cm to 10 mS/cm, 1.5 mS/cm to 9.5 mS/cm, 2 mS/cm to 9 mS/cm or 2.5 mS/cm to 8.5 mS/cm.

In another aspect of main aspect 1, wherein the silica particles are fumed silica particles that are not surface treated or modified by any chemical species, and wherein the fumed silica particles are not covalent bonded with either a negatively or a positively charged species. The CMP composition of claim 1, wherein the abrasive comprises fumed silica particles present in an amount of from about 0.25 wt. % to 10.0 wt. %, 1 wt. % to 8.0 wt. % or 2.0 wt. % to 6.0 wt. %. In another aspect of main aspect 1, wherein the first chemical additive comprises histidine, glutamic acid, glycine, alanine, aspartic acid, serine, arginine, or tryptophan, or mixtures thereof. In another aspect of main aspect 1, wherein the first chemical additive comprises L-Histidine present in an amount between about 0.001 wt. % to 1.0 wt. %, 0.01 wt. % to 0.5 wt. % and about 0.02 wt. % to 0.25 wt. %. In another aspect of main aspect 1, wherein the oxidizing agent is hydrogen peroxide. In another aspect of main aspect 1, wherein the silica particles are selected from the group consisting of colloidal silica, high purity silica, and fumed silica. In another aspect of main aspect 1, wherein the silicate comprises sodium silicate, potassium silicate, aluminum silicate, calcium silicate or tetramethylammonium silicate. In another aspect of main aspect 1, wherein the surfactant is present and is selected from the group consisting of a non-ionic surfactant, an anionic surfactant, a cationic surfactant, an ampholytic surfactant, and mixtures thereof.

In a second main aspect, a method of a selective chemical mechanical polishing comprises: a) providing a semiconductor substrate having a surface containing a first material and at least one second material; wherein the first material is silicon dioxide such as TEOS or USG (undoped silicon glass) and the second material is copper, and barrier film; b) providing a polishing pad; c) providing a chemical mechanical polishing composition comprising: water; a first chemical additive comprising one or more amino acids having at least one carboxyl group and preferably at least one amino group —NH₂ and preferably at least one imidazole group and mixtures thereof; a second chemical additive comprising silicate; an oxidizing agent; an abrasive comprising silica particles; a corrosion inhibitor; and, optionally, a surfactant; a pH adjusting agent, wherein the polishing composition has a pH of from about 9 to about 11, wherein the polishing composition has a POU conductivity of 1 mS/cm to 10 mS/cm, 1.5 mS/cm to 9.5 mS/cm, 2 mS/cm to 9 mS/cm or 2.5 mS/cm to 8.5 mS/cm; and d) polishing the surface of the semiconductor substrate to selectively remove the first material.

In another aspect of main aspect 2, the pH adjusting agent is present and is selected from the group consisting of nitric acid, sulfuric acid, potassium hydroxide, sodium hydroxide, ammonia, tetraethylammonium hydroxide, ethylenediamine, piperazine, polyethyleneimine, and mixtures thereof. In another aspect of main aspect 2, wherein the abrasive is present in an amount of from about 0.25 wt. % to about 5.0 wt. %. In another aspect of main aspect 2, the oxidizing agent is selected from the group consisting of hydrogen peroxide, periodic acid, potassium iodate, potassium permanganate, ammonium persulfate, ammonium molybdate, ferric nitrate, nitric acid, potassium nitrate, ammonia, and mixtures thereof. In another aspect of main aspect 2, the first chemical additive comprises histidine, glutamic acid, glycine, alanine, aspartic acid, serine, arginine, or tryptophan, or mixtures thereof. In another aspect of main aspect 2, the first chemical additive comprises L-Histidine present in an amount between about 0.001 wt. % to 1.0 wt. %, 0.01 wt. % to 0.5 wt. % and about 0.02 wt. % to 0.25 wt. %. In another aspect of main aspect 2, the oxidizing agent is hydrogen peroxide present at from about 0.1 wt. % to about 3.0 wt. %. In another aspect of main aspect 2, the silica particles comprise alumina or ceria. In another aspect of main aspect 2, the silicate comprises sodium silicate, potassium silicate, aluminum silicate, calcium silicate or tetramethylammonium silicate. In another aspect of main aspect 2, the surfactant is present and selected from the group consisting of a non-ionic surfactant, an anionic surfactant, a cationic surfactant, an ampholytic surfactant, and mixtures thereof.

In a third main aspect, a method for chemical mechanical planarization of a semiconductor device comprising at least one surface comprising silicon dioxide, the method comprising the steps of: a. contacting the at least one surface comprising silicon dioxide with a polishing pad; b. delivering to the at least one surface comprising silicon dioxide a polishing composition comprising: water; an oxidizing agent; an abrasive comprising silica particles; a first chemical additive comprising one or more amino acids having at least one carboxyl group and preferably at least one amino group —NH₂ and preferably at least one imidazole group and mixtures thereof; a second chemical additive comprising silicate; a corrosion inhibitor; and, optionally, a surfactant; a pH adjusting agent, wherein the polishing composition has a pH of from about 9 to about 11; wherein the polishing composition has a POU conductivity of 1 mS/cm to 10 mS/cm, 1.5 mS/cm to 9.5 mS/cm, 2 mS/cm to 9 mS/cm or 2.5 mS/cm to 8.5 mS/cm; and c. polishing the at least one surface comprising silicon dioxide with the polishing composition to at least partially remove the at least one surface comprising silicon dioxide.

In another aspect of main aspect 3, the pH adjusting agent is present and is selected from the group consisting of nitric acid, sulfuric acid, potassium hydroxide, sodium hydroxide, ammonia, tetraethylammonium hydroxide, ethylenediamine, piperazine, polyethyleneimine, and mixtures thereof. In another aspect of main aspect 3, the abrasive comprises fumed silica present in an amount of from about 0.25 wt. % to about 5.0 wt. %. In another aspect of main aspect 3, the oxidizing agent is selected from the group consisting of hydrogen peroxide, periodic acid, potassium iodate, potassium permanganate, ammonium persulfate, ammonium molybdate, ferric nitrate, nitric acid, potassium nitrate, ammonia, and mixtures thereof. In another aspect of main aspect 3, the oxidizing agent is selected from the group consisting of hydrogen peroxide and urea-hydrogen peroxide. In another aspect of main aspect 3, the oxidizing agent is hydrogen peroxide. In another aspect of main aspect 3, the oxidizing agent is present at from about 0.25% to about 3%. In another aspect of main aspect 3, the silica particles comprise alumina or ceria. In another aspect of main aspect 3, the first chemical additive comprises L-Histidine present in an amount between about 0.0025 wt. % to 2.5 wt. %, 0.025 wt. % to 1.25 wt. % and about 0.05 wt. % to 0.625 wt. %.

In a fourth main aspect, a system for chemical mechanical planarization of a semiconductor device comprising at least one surface; comprising: the semiconductor device comprising at least one surface, wherein the at least one surface has (1) a barrier layer comprising silicon dioxide; (2) an interconnect metal layer selected from the group of copper, tungsten, cobalt, aluminum, or their alloys; and (3) a porous or non-porous dielectric layer; a polishing pad; and the chemical mechanical polishing (CMP) composition in any one of claims 1 to 10.

In a fifth main aspect, a concentrated CMP composition comprising: water; an oxidizing agent; an abrasive comprising silica particles; a first chemical additive comprising one or more amino acids having at least one carboxyl group and preferably at least one amino group —NH₂ and preferably at least one imidazole group and mixtures thereof; and a second chemical additive comprising a silicate; and, optionally, a corrosion inhibitor; a surfactant; a pH adjusting agent; a biocide; wherein the composition has a pH of 7 to 12, 8 to 11.5, or 10 to 11; and wherein the composition has a conductivity of 1 mS/cm to 15 mS/cm, 7 mS/cm to 14 mS/cm, 9 mS/cm to 13 mS/cm or 10 mS/cm to 12.5 mS/cm.

In another aspect of main aspect 5, the silica particles are fumed silica particles that are not surface treated or modified by any chemical species, and wherein the fumed silica particles are not covalent bonded with either a negatively or a positively charged species. In another aspect of main aspect 5, the abrasive comprises fumed silica particles present in an amount of from about 0.625 wt. % to 25.0 wt. %, 2.5 wt. % to 20.0 wt. %, or 5.0 wt. % to 15.0 wt. %. In another aspect of main aspect 5, the first chemical additive comprises histidine, glutamic acid, glycine, alanine, aspartic acid, serine, arginine, or tryptophan, or mixtures thereof. In another aspect of main aspect 5, the first chemical additive comprises L-Histidine present in an amount between about 0.0025 wt. % to 2.5 wt. %, 0.025 wt. % to 1.25 wt. % and about 0.05 wt. % to 0.625 wt. %. In another aspect of main aspect 5, the silica particles are selected from the group consisting of colloidal silica, high purity silica, and fumed silica. In another aspect of main aspect 5, the silicate comprises sodium silicate, potassium silicate, aluminum silicate, calcium silicate or tetramethylammonium silicate.

The polished oxide films can be Chemical vapor deposition (CVD), Plasma Enhance CVD (PECVD), High Density Deposition CVD (HDP), or spin on oxide films or undoped silicon glass films.

### BRIEF DESCRIPTION OF SEVERAL VIEWS OF THE DRAWINGS

FIG. 1 shows mean particle size data of concentrated slurry 4A and concentrated slurry 4B over time.

### DETAILED DESCRIPTION

The subject matter of the present application satisfies the need by providing Chemical mechanical Planarization (CMP) polishing compositions, methods, and systems for barrier CMP applications.

The disclosed CMP polishing composition has a unique combination of using fumed silica particles, and suitable chemical additives such as a soluble silicate, a surfactant, a base, and an amino acid having at least one carboxyl group and at least one amino group —NH₂ and an imidazole ring for example, L-histidine to provide high removal rates of silicon dioxide (such as TEOS) for achieving a topographically corrected wafer surface with low defects.

A present barrier CMP slurry achieves high material removal rates with a low POU conductivity. A benefit of a low POU conductivity is that it imparts good colloidal stability for such a slurry when it is concentrated to greater than POU. This allows the barrier CMP slurry to be concentrated to from 2.0 to about 5.0 greater than POU, which benefits the end user in terms of easier handling, enabling higher throughput, and improved cost of ownership.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the subject matter of the present application (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the subject matter of the application and does not pose a limitation on the scope of the claims unless explicitly stated. No language in the specification should be construed as indicating any non-claimed element as essential to the practice of the claimed subject matter. The use of the term “comprising” in the specification and the claims includes the narrower language of “consisting essentially of” and “consisting of.”

Variations of the embodiments described herein may become apparent to those of ordinary skill in the art upon reading the foregoing description. The inventors expect skilled artisans to employ such variations as appropriate, and the inventors intend for the claimed subject matter to be practiced otherwise than as specifically described herein. Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

For ease of reference, “microelectronic device” corresponds to semiconductor substrates, flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” is not meant to be limiting in any way and includes any substrate that will eventually become a microelectronic device or microelectronic assembly.

“Substantially free” is defined herein as less than 0.001 wt. %. “Substantially free” also includes 0.000 wt. %. The term “free of” means 0.000 wt. %.

As used herein, “about” is intended to correspond to +5%, preferably +2% of the stated value.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.00001 weight percent, based on the total weight of the composition in which such components are employed.

There are several specific aspects of the presently disclosed subject matter.

In one aspect, there is provided a CMP polishing composition comprises:
Fumed silica particles;
at least five different chemical additives;
a solvent; and
an organic small molecule rate boosting additive;
an inorganic rate boosting additive;
a pH adjustor,
a surfactant;
and an oxidizer
and optionally a corrosion inhibitor
the composition has a pH of 7 to 12, 8 to 11.5, or 10 to 11.

The composition has a POU conductivity of 1 mS/cm to 10 mS/cm, 1.5 mS/cm to 9.5 mS/cm, 2 mS/cm to 9 mS/cm or 2.5 mS/cm to 8.5 mS/cm.

The silica particles include, but are not limited to colloidal silica, high purity colloidal silica, and fumed silica. The particles can have any suitable shapes: spherical, non-spherical such as cocoon shaped, branched, or aggregated silica particles.

The silica particles are not surface treated or modified by any chemical species, such as a nitrogen-containing species for example amino silane. Thus, the surface of the particles is not covalent bonded with either a negatively or a positively charged species.

The Mean Particle Size (MPS) of silica particles is ranged from 10 nm to 500 nm, the preferred particle size is ranged from 20 nm to 300 nm, the more preferred particle size is ranged from 50 nm to 250 nm. The MPS is measured by dynamic light scattering (DLS).

The preferred silica particles are fumed silica particles with a multi-aggregated morphology.

The solvent includes but is not limited to deionized (DI) water, distilled water, and alcoholic organic solvents.

The preferred solvent is DI water.

The first type of the chemical additive includes amino acids having at least one carboxyl group and preferably at least one amino group —NH₂ and preferably at least one imidazole group.

The chemical additive has a general molecular structure as listed below:

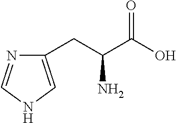 [SMILES: N[C@@H](Cc1c[nH]cn1)C(=O)O]

The preferred first type of chemical additives include but are not limited to: histidine, glutamic acid, glycine, alanine, aspartic acid, serine, arginine, and tryptophan.

The second type of chemical additives include but are not limited to a silicate, preferably a silicate containing salt including but not limited to sodium silicate, potassium silicate, aluminum silicate, calcium silicate and tetramethylammonium silicate.

The third type of chemical additives include but are not limited to an alkaline compound for pH adjusting such as potassium hydroxide, sodium hydroxide, cesium hydroxide, ammonium hydroxide, tetramethylammonium hydroxide, tetraethylammonium hydroxide, tetrabutylammonium hydroxide, tetrabutylphosphonium hydroxide, piperazine, and ethylenediamine.

The fourth type of chemical additives include but are not limited to a surfactant, preferably a nonionic surfactant such as an ethoxylated acetylenic diol, such as 2,5,8,11 tetramethyl 6 dodecyn-5,8 diol ethoxylate (Dynol 607).

The fifth type of chemical additives include but are not limited to an oxidizer for the oxidation of metal surfaces during CMP. Oxidizers can include hydrogen peroxide, ammonium persulfate, potassium periodate, and potassium permanganate.

Optionally a corrosion inhibitor can be used and can include but are not limited to 1H-benzotriazole, 1,2,4-triazole and amitrole.

In another aspect, there is provided a method of CMP polishing a substrate having at least one surface comprising silicon dioxide using the CMP polishing composition described above.

In yet another aspect, there is provided a system of CMP polishing a substrate having at least one surface comprising silicon dioxide using the CMP polishing composition described above.

The polished oxide films can be Chemical vapor deposition (CVD), Plasma Enhance CVD (PECVD), High Density Deposition CVD (HDP), or spin on oxide films or undoped silicon glass films.

The substrate disclosed above can further comprises at least a surface containing a silicon dioxide such as TEOS or undoped silicon glass (USG) copper, or both silicon dioxide and copper. The removal selectivity of Cu:SiO₂ is from 1 to 5, 1 to 4, 1 to 3, 1 to 2 or 0.1 to 1.

Other aspects, features, and embodiments of the present disclosure will be more fully apparent from the ensuing disclosure and appended claims.

The embodiments of the present disclosure can be used alone or in combinations with each other.

The following non-limiting examples are presented to further illustrate the presently disclosed subject matter.

### CMP Methodology

In the examples presented below, CMP experiments were run using the procedures and experimental conditions given below.

### Glossary

### Components

Fumed silica particles: used as abrasive having an aggregated branched morphology a primary particle size of approximately 10-30 nm; and a secondary particle size ranged from 50 to 250 nm.

The particles AeroDisp W7225G were supplied by the Evonik Corporation in the United States.

Chemical additives, such as L-Histidine, L-glutamic acid and other chemical raw materials were purchased from Sigma-Aldrich (Merck KGaA) of highest commercial grade and used as received unless otherwise specified.

Polishing Pad: Fujibo H800, was used during CMP, supplied by Fujibo Ehime Co., Ltd. 272 Oshinden, Saijo-shi, Ehime 799-1342, Japan.

### Parameters

### General

Å or A: angstrom(s)—a unit of length
nm: nanometers—a unit of length
MPS: mean particle size, the average of the particle size distribution in a sample as measured by dynamic light scattering
° C.: degrees Celsius—a unit of temperature
BP: back pressure, in psi units
CMP: chemical mechanical planarization=chemical mechanical polishing
CS: carrier speed
DF: Down force: pressure applied during CMP, units psi
min: minute(s)
ml: milliliter(s)
mV: millivolt(s)
psi: pounds per square inch
PS: platen rotational speed of polishing tool, in rpm (revolution(s) per minute)
SF: slurry flow, ml/min
Wt. %: weight percentage (of a listed component)
TEOS: tetraethyl orthosilicate
HDP: high density plasma deposited TEOS
TEOS Removal Rates: Measured TEOS removal rate at a given down pressure. The down pressure of the CMP tool was 2.5 psi in the examples listed below.

### Metrology

Films were measured with a ResMap CDE, model 168, manufactured by Creative Design Engineering, Inc, 20565 Alves Dr., Cupertino, CA, 95014. The ResMap tool is a four-point probe sheet resistance tool. Forty-nine-point diameter scan at 5 mm edge exclusion for film was taken.

Films were measured with a an Optiprobe 5000, manufactured by Therma-Wave, Inc., 1250 Reliance Way, Fremont, CA, 94539. The Optiprobe 5000 measure film thickness of dielectric materials via ellipsometry

### CMP Tool

The CMP tool that was used is a 200 mm Mirra, or 300 mm Reflexion manufactured by Applied Materials, 3050 Boweres Avenue, Santa Clara, California, 95054. An H800 pad supplied by Fujibo Ehime Co., Ltd. 272 Oshinden, Saijo-shi, Ehime 799-1342, Japan.

### Polishing Condition:

Downforce—2.5 psi
Slurry flow rate—200 mL/min
Platen speed—93 RPM
Head speed—87 RPM

### Wafers

Polishing experiments were conducted using TEOS wafers. These blanket wafers were purchased from Silicon Valley Microelectronics, 2985 Kifer Rd., Santa Clara, CA 95051.

### Polishing Experiments

In blanket wafer studies, TEOS blanket wafers were polished at baseline conditions.

All other reagents and solvents were purchased from Sigma-Aldrich (Merck KGaA) of highest commercial grade and used as received unless otherwise specified.

### Working Example 1

In working example 1, all CMP polishing composition comprised 1.06% potassium silicate, 0.04% potassium hydroxide, 0.002% Dynol 607 and 0.1% hydrogen peroxide.

In the working example, several different additives were used in samples 1B thru 1F in comparison to 1A.

Compositions 1B to 1F had a point of use (POU) conductivity between 6 to 6.37 mS/cm in comparison to composition 1A which had a POU conductivity of 8.04 mS/cm.

TABLE 1

| | Abrasive | Additive | | | | |
|---|---|---|---|---|---|---|
| | Fumed | Potassium | | | | |
| | Silica | Oxalate | L-Glutamic | Glycine | Oxalic Acid | L-Histidine |
| Slurry | (%) | (%) | Acid (%) | (%) | (%) | (%) |
| 1A, | 5.8 | 0.19 | 0 | 0 | 0 | 0 |
| Control | | | | | | |
| 1B | 5.8 | 0 | 0 | 0 | 0 | 0 |
| 1C | 5.8 | 0 | 0.08 | 0 | 0 | 0 |
| 1D | 5.8 | 0 | 0 | 0.1 | 0 | 0 |
| 1E | 5.8 | 0 | 0 | 0 | 0.1 | 0 |
| 1F | 5.8 | 0 | 0 | 0 | 0 | 0.08 |

| | POU Conductivity | TEOS Removal Rate |
|---|---|---|
| | (mS/cm) | (Angstroms/min) |
| Slurry 1A, Control | 8.04 | 2543 |
| Slurry 1B | 6.02 | 2428 |
| Slurry 1C | 6.08 | 2442 |
| Slurry 1D | 6.00 | 1953 |
| Slurry 1E | 6.37 | 1919 |
| Slurry 1F | 6.02 | 2642 |

As shown in Table 1, Slurry 1F, which includes the additive L-Histidine, achieves the highest TEOS removal rate at the lowest possible concentration and POU conductivity when compared to all other additives. Slurries 1B through 1F have a lower POU conductivity when compared to the control 1A. When the potassium oxalate is removed and nothing is added in its place, the POU conductivity drops 2 mS/cm and the TEOS removal rate drops. When a replacement additive is added (1C-1F) and an attempt is made to maintain a similar POU conductivity, L-Histidine (1F) stands out for increasing the removal rate of TEOS when compared to the control which achieving a lower conductivity of about 6 mS/cm. Slurries 1B-1F are comparable based on POU conductivity. High formulation conductivity is a widely accepted mechanism for increasing removal rate in barrier slurries. However, the downside of high conductivity is that it compromises the stability of the formulation. The L-Histidine additive achieves better removal rate performance at a lower conductivity.

The TEOS removal rate for sample 1F is 4% higher than the sample 1A control which has a POU conductivity that is 2 mS/cm higher than sample 1F. Sample 1F has a TEOS removal rate that is 26% higher than sample 1D which has nearly the same POU conductivity of 6.02 mS/cm as sample 1F.

### Working Example 2

In working example 2, all CMP polishing composition comprised 1.06% potassium silicate, 0.04% potassium hydroxide, 0.002% Dynol 607 and 0.1% hydrogen peroxide.

In working example 2 compositions 2A and 2C are either fumed silica or colloidal silica which both have the additive potassium oxalate and these are compared to compositions 2B and 2D which both have the additive L-Histidine

TABLE 2

| | Abrasive | | Additive | | | |
|---|---|---|---|---|---|---|
| | Fumed | Colloidal | Potassium | L- | POU | TEOS Removal |
| | Silica | Silica | oxalate | Histidine | Conductivity | Rate |
| | (%) | (%) | (%) | (%) | (mS/cm) | (Angstroms/min) |
| Slurry 2A, | 5.8 | 0 | 0.19 | 0 | 7.58 | 2307 |
| Control | | | | | | |
| Slurry 2B | 5.8 | 0 | 0 | 0.08 | 5.88 | 2582 |
| Slurry 2C | 0 | 5.8 | 0.19 | 0 | 4.99 | 1506 |
| Slurry 2D | 0 | 5.8 | 0 | 0.08 | 2.73 | 1539 |

As shown in Table 2, samples 2B and 2D with L-Histidine have significantly lower POU conductivity when compared to samples 2A and 2C with potassium oxalate.

The POU conductivity of sample 2B is 1.7 mS/cm lower than sample 2A. The POU conductivity of sample 2D is 2.26 mS/cm lower than sample 2C.

In table 2 it is observed that the fumed silica compositions 2A and 2B greatly increases TEOS removal rate over the colloidal silica samples 2C and 2D. For sample 2B, when L-Histidine replaces potassium oxalate, the TEOS removal rate increases 10%. For sample 2D the TEOS removal rate is only 2% higher than sample 2D, but at a much lower POU conductivity.

### Working Example 3

In working example 3, all CMP polishing composition comprised 1.06% potassium silicate, 0.04% potassium hydroxide, 0.002% Dynol 607 and 0.1% hydrogen peroxide.

In addition, sample 3C has the same chemical composition as 3B but contains 1% lower fumed silica concentration than both 3A and 3B.

The compositions had a conductivity from 5.66 to 7.81 at point of use (POU).

TABLE 3

| | | | | | TEOS |
|---|---|---|---|---|---|
| | Abrasive | Additive | | POU | Removal |
| | Fumed | Potassium | L- | Conduc- | Rate |
| | Silica | oxalate | Histidine | tivity | (Ang- |
| | (%) | (%) | (%) | (mS/cm) | stroms/min) |
| Slurry 3A, | 5.8 | 0.19 | 0 | 7.81 | 2155 |
| Control | | | | | |
| Slurry 3B | 5.8 | 0 | 0.08 | 5.66 | 2396 |
| Slurry 3C | 4.8 | 0 | 0.08 | 5.68 | 2288 |

As shown in Table 3, the replacement of potassium oxalate with L-histidine reduces the POU conductivity of sample 3B by 2.15 mS/cm from sample 3A while the corresponding TEOS removal rate increases 11%.

Also shown in table is that when the fumed silica concentration is decreased by 1% from sample 3B to 3C the TEOS removal rate decreases 4.5%. The removal rate of sample 3C is still higher than sample 3A which shows that L-Histidine as a replacement for potassium oxalate is still able to achieve high TEOS removal rates with lower fumed silica concentration and a lower POU conductivity.

### Working Example 4

In working example 4, all CMP polishing composition are comprised of 2.65% potassium silicate, 0.1% potassium hydroxide and 0.005% Dynol 607 and no hydrogen peroxide. These values represent a 2.5 times increase in concentration for samples 3A and 3C from working example 3. Similarly, the fumed concentration for samples 4A and 4B are increased 2.5 times to their POU concentrations in samples 3A and 3C in working example 3.

Samples 4A and 4B were exposed to an elevated temperature of 50° C. for up to eleven days where the mean particle size of the fumed silica in the samples was measured at regular intervals during this time. This test is a measure of colloidal stability in the formulation where an increasing trend line is an indicator of colloidal instability.

TABLE 4

| | Abrasive | Additive | | |
|---|---|---|---|---|
| | Fumed | Potassium | | Concentrated |
| | Silica | oxalate | L-Histidine | Conductivity |
| | (%) | (%) | (%) | (mS/cm) |
| Concentrated | 14.5 | 0.48 | 0 | 15.9 |
| Slurry 4A, | | | | |
| Control | | | | |
| Concentrated | 12 | 0 | 0.21 | 12 |
| Slurry 4B | | | | |

| | Mean Particle size (nm) vs Days @ 50 C. | | | | |
|---|---|---|---|---|---|
| | 0 | 2 | 4 | 7 | 11 |
| Concentrated | 167 | 178 | 181 | 193 | 207 |
| Slurry 4A, | | | | | |
| Control | | | | | |
| Concentrated | 168 | 171 | 169 | 169 | 169 |
| Slurry 4B | | | | | |

The working example shows that concentrated Sample 4B has the additive L-Histidine replacing potassium oxalate, the additive used in concentrated sample 4A. Sample 4B also has 2.5% lower fumed silica concentration compared to sample 4A based on data from table 3. All other components are fixed in concentration.

The working example shows the replacement of potassium oxalate with L-Histidine in sample 4B results in a decrease of slurry conductivity of 3.9 mS/cm.

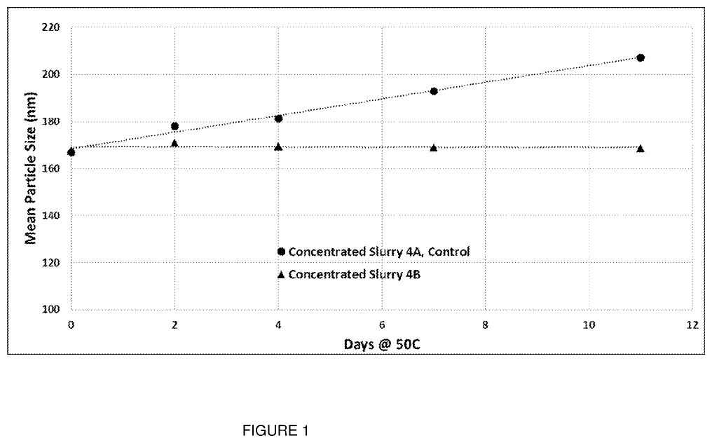

FIG. 1 shows that sample 4B remains stable over 11 days at 50° C., whereas sample 4A shows an increase of 40 nm in mean particle size over the same time frame. This example clearly shows that the fumed silica in composition of 4B has a stable MPS at 2.5 times the concentration of the POU sample 3C in working example 3. This is due to the significant decrease in concentrated conductivity of sample 4B when compared to sample 4A.

The embodiments listed above, including the working example, are exemplary of numerous embodiments that may be made without departing from the scope of this application. It is contemplated that numerous other configurations of the process may be used, and the materials used in the process may be elected from numerous materials other than those specifically disclosed.

1. A CMP composition comprising:
water;
an oxidizing agent;
an abrasive comprising silica particles;
a first chemical additive comprising one or more amino acids having at least one carboxyl group and preferably at least one amino group —NH₂ and preferably at least one imidazole group and mixtures thereof; and
a second chemical additive comprising a silicate;
and, optionally,
a corrosion inhibitor;
a surfactant;
a pH adjusting agent;
a biocide;
wherein the polishing composition has a pH of 7 to 12, 8 to 11.5, or 10 to 11; and
wherein the polishing composition has a POU conductivity of 1 mS/cm to 10 mS/cm, 1.5 mS/cm to 9.5 mS/cm, 2 mS/cm to 9 mS/cm, or 2.5 mS/cm to 8.5 mS/cm.

2. The CMP composition of claim 1, wherein the silica particles are fumed silica particles that are not surface treated or modified by any chemical species, and wherein the fumed silica particles are not covalent bonded with either a negatively or a positively charged species.

3. The CMP composition of claim 1, wherein the abrasive comprises fumed silica particles present in an amount of about 0.25 wt. % to about 10.0 wt. %, about 1.0 wt. % to about 8.0 wt. %, or about 2.0 wt. % to about 6.0 wt. %.

4. The CMP composition of claim 1, wherein the first chemical additive comprises histidine, glutamic acid, glycine, alanine, aspartic acid, serine, arginine, or tryptophan, or mixtures thereof.

5. The CMP composition of claim 4, wherein the first chemical additive comprises L-Histidine present in an amount ranging from about 0.001 wt. % to about 1.0 wt. %, from about 0.01 wt. % to about 0.5 wt. %, or from about 0.02 wt. % to about 0.25 wt. %.

6. The CMP composition of claim 1, wherein the oxidizing agent is hydrogen peroxide.

7. The CMP composition of claim 1, wherein the silica particles are selected from the group consisting of colloidal silica, high purity silica, and fumed silica.

8. The CMP composition of claim 1, wherein the silicate comprises sodium silicate, potassium silicate, aluminum silicate, calcium silicate or tetramethylammonium silicate.

9. The CMP composition of claim 1, wherein the surfactant is present and is selected from the group consisting of a non-ionic surfactant, an anionic surfactant, a cationic surfactant, an ampholytic surfactant, and mixtures thereof.

10. A method of a selective chemical mechanical polishing comprising:
a) providing a semiconductor substrate having a surface containing a first material and at least one second material; wherein the first material is silicon dioxide such as TEOS or USG (undoped silicon glass) and the second material is copper, and barrier film;
b) providing a polishing pad;
c) providing a chemical mechanical polishing composition comprising:
water;
a first chemical additive comprising one or more amino acids having at least one carboxyl group and preferably at least one amino group —NH₂ and preferably at least one imidazole group and mixtures thereof;
a second chemical additive comprising silicate;
an oxidizing agent;
an abrasive comprising silica particles;
a corrosion inhibitor;
and, optionally,
a surfactant;
a pH adjusting agent,
wherein the polishing composition has a pH of from about 9 to about 11;
wherein the polishing composition has a POU conductivity of 1 mS/cm to 10 mS/cm, 1.5 mS/cm to 9.5 mS/cm, 2 mS/cm to 9 mS/cm, or 2.5 mS/cm to 8.5 mS/cm; and
d) polishing the surface of the semiconductor substrate to selectively remove the first material.

11. The method of claim 10, wherein the pH adjusting agent is present and is selected from the group consisting of nitric acid, sulfuric acid, potassium hydroxide, sodium hydroxide, ammonia, tetraethylammonium hydroxide, ethylenediamine, piperazine, polyethyleneimine, and mixtures thereof.

12. The method of claim 10, wherein the abrasive is present in an amount of from about 0.25 wt. % to about 5.0 wt. %.

13. The method of claim 10, wherein the oxidizing agent is selected from the group consisting of hydrogen peroxide, periodic acid, potassium iodate, potassium permanganate, ammonium persulfate, ammonium molybdate, ferric nitrate, nitric acid, potassium nitrate, ammonia, and mixtures thereof.

14. The method of claim 10, wherein the first chemical additive comprises histidine, glutamic acid, glycine, alanine, aspartic acid, serine, arginine, or tryptophan, or mixtures thereof.

15. The method of claim 14, wherein the first chemical additive comprises L-Histidine present in an amount between about 0.001 wt. % to 1.0 wt. %, 0.01 wt. % to 0.5 wt. % and about 0.02 wt. % to 0.25 wt. %.

16. The method of claim 10, wherein the oxidizing agent is hydrogen peroxide present at from about 0.1 wt. % to about 3.0 wt. %.

17. The method of claim 10, wherein the silica particles comprise alumina or ceria.

18. The method of claim 10, wherein the silicate comprises sodium silicate, potassium silicate, aluminum silicate, calcium silicate or tetramethylammonium silicate.

19. The method of claim 10, wherein the surfactant is present and selected from the group consisting of a non-ionic surfactant, an anionic surfactant, a cationic surfactant, an ampholytic surfactant, and mixtures thereof.

20. A system for chemical mechanical planarization of a semiconductor device comprising at least one surface; comprising:
the semiconductor device comprising at least one surface, wherein the at least one surface has (1) a barrier layer comprising silicon dioxide; (2) an interconnect metal layer selected from the group of copper, tungsten, cobalt, aluminum, or their alloys; and (3) a porous or non-porous dielectric layer;
a polishing pad; and
the chemical mechanical polishing (CMP) composition of claim 1.
